(19) United States
(12) Patent Application Publication
(10) Pub. No.: US 2024/0223185 A1
(43) Pub. Date: Jul. 4, 2024

(54) Electronic Device

(71) Applicant: InnoLux Corporation, Miao-Li County (TW)

(72) Inventors: Chih-Yang CHEN, Miao-Li County (TW); Tao-Sheng CHANG, Miao-Li County (TW); Hsing-Yi LIANG, Miao-Li County (TW)

(73) Assignee: InnoLux Corporation, Miao-Li County (TW)

(21) Appl. No.: 18/513,623

(22) Filed: Nov. 19, 2023

(30) Foreign Application Priority Data
Dec. 28, 2022 (CN) 202211692022.X

(51) Int. Cl. H03K 17/687; B41J 2/045

(52) U.S. Cl. CPC H03K 17/6872; B41J 2/04541; B41J 2/0455; B41J 2/0458

(57) ABSTRACT

An electronic device includes a heater, and a sampling and holding circuit coupled to the heater. The sampling and holding circuit includes a sampling unit, a register unit and a feedback unit. The sampling unit is for receiving a data signal. The register unit has an input terminal and an output terminal. The input terminal is coupled to the sampling unit, and the output terminal is for outputting a first signal. The feedback unit is coupled to the input terminal and the output terminal of the register unit. When the feedback unit is turned on, the feedback unit feeds the first signal to the input terminal.

### BACKGROUND OF THE DISCLOSURE

### 1. Field of the Disclosure

The present disclosure is related an electronic device, and more particularly a print head driving circuit constructed with thin film transistors.

### 2. Description of the Prior Art

Inkjet printing is a type of computer printing that recreates a digital image by propelling droplets of ink onto paper and plastic substrates. Inkjet printers can range from small inexpensive consumer models to expensive professional machines.

There are different types of inkjet printers, but one common type is the thermal inkjet. Thermal inkjet (TIJ) is a type of printing technology that uses heat to eject ink droplets from a cartridge onto a substrate. TIJ printers are smaller, cheaper, and easier to use than continuous inkjet (CIJ) printers, which use electric charges and pressurized ink streams to print. TIJ printers can produce high-quality prints on various surfaces, such as paper, plastic, metal, and glass. TIJ printers are ideal for applications that require low maintenance, high reliability, and odor-free printing.

Thermal inkjet (TIJ) printing is a type of non-impact printing that creates an image by ejecting small droplets of ink onto a substrate. The ink is heated, causing it to vaporize and expand. This expansion creates a pressure difference that forces the ink out of the nozzle and onto the substrate. TIJ printers are used in a wide variety of applications, including labeling, direct-to-garment printing, and signage. TIJ printers offer a number of advantages over other types of printers, including high speed, high quality, and versatility. Overall, TIJ printers are a versatile and cost-effective printing solution for a wide variety of applications.

A print head driving circuit is a circuit that controls the firing of the inkjet nozzles in an inkjet printer. The circuit is typically comprised of a power supply, a driver chip, and a timing circuit. The power supply provides the high voltage needed to fire the nozzles, the driver chip controls the timing and duration of the firing, and the timing circuit ensures that the nozzles are fired in the correct order. The power supply is generally a high voltage transformer that steps up the voltage from the printer's main power supply to the high voltage needed to fire the nozzles. The driver chip is a digital chip that receives signals from the printer's controller and uses these signals to control the firing of the nozzles. The timing circuit is a circuit that generates the timing signals for the driver chip. The print head driving circuit is a critical component of an inkjet printer. It is responsible for ensuring that the print head are fired correctly and in the correct order. This is essential for producing high quality prints.

The print head driving circuits are often built with complementary metal oxide semiconductor (CMOS) transistors. However, building print head driving circuits with thin film transistors (TFT) would have some critical advantages. Thin-film transistors (TFTs) are a special kind of field-effect transistors (FETs) that use a thin layer of semiconductor material deposited on a non-conducting substrate, such as glass. TFTs are widely used in liquid-crystal displays (LCDs), where they act as switches for each pixel, allowing them to turn on and off quickly. TFTs can be made from different semiconductor materials, such as silicon, metal oxides, organic compounds, or carbon nanotubes. TFTs have various applications in flexible electronics, transparent electronics, and paper electronics. Therefore, thin film transistors are more suitable for making large-area print head driving circuits for the above reasons. Yet, compared with CMOS devices, TFT devices have higher leakage current and longer signal rising and falling time, which can cause serious problems to a print head driving circuit.

### SUMMARY OF THE DISCLOSURE

An embodiment provides an electronic device including a heater, and a sampling and holding circuit coupled to the heater. The sampling and holding circuit includes a sampling unit, a register unit and a feedback unit. The sampling unit is used to receive a data signal. The register unit has an input terminal and an output terminal. The input terminal is coupled to the sampling unit and the output terminal is used to output a first signal. The feedback unit is coupled to the input terminal and the output terminal of the register unit. When the feedback unit is turned on, the feedback unit feeds back the first signal to the input terminal.

An embodiment provides an electronic device including a sampling and holding circuit, an output buffer and a heater. The sampling and holding circuit is used to receive a data signal and output a first signal. The output buffer is coupled to the sampling and holding circuit and used to receive the first signal and output a driving signal. The heater is coupled to the output buffer and used to receive the driving signal. A rising time of the driving signal has a first time period. A falling time of the driving signal has a second time period. The first time period is longer than the second time period.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a diagram of an electronic device of an embodiment.

FIG. 2 is a circuit diagram of a sampling and holding circuit in FIG. 1.

FIG. 3 is a timing diagram of operation signals of the sampling and holding circuit in FIG. 2 of an embodiment.

FIG. 4 is a circuit diagram of a sampling and holding circuit in FIG. 1 of another embodiment.

FIG. 5 is a circuit diagram of a sampling and holding circuit in FIG. 1 of another embodiment.

FIG. 6 is a circuit diagram of sampling and holding circuit in FIG. 1 of another embodiment.

FIG. 7 is a circuit diagram of a sampling and holding circuit in FIG. 1 of another embodiment.

FIG. 8 is a circuit diagram of an output buffer in FIG. 1 of an embodiment.

FIG. 9 is a timing diagram of driving signals at the output terminal of the output buffer in FIG. 8.

FIG. 10 is a circuit diagram of an output buffer in FIG. 1 of another embodiment.

FIG. 11 is a circuit diagram of an output buffer in FIG. 1 of another embodiment.

### DETAILED DESCRIPTION

The present disclosure may be understood by reference to the following detailed description, taken in conjunction with the drawings as described below, and for purposes of illustrative clarity and being easily understood by the readers, various drawings of this disclosure may be simplified, and the elements in various drawings may not be drawn to scale. In addition, the number and dimension of each element shown in drawings are just illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function. In the following description and in the claims, the terms “comprise”, “include” and “have” are used in an open-ended fashion, and thus should be interpreted to mean “include, but not limited to . . . ”.

The direction terms used in the following embodiment such as up, down, left, right, in front of or behind are just the directions referring to the attached figures. Thus, the direction terms used in the present disclosure are for illustration, and are not intended to limit the scope of the present disclosure. It should be noted that the elements which are specifically described or labeled may exist in various forms for those skilled in the art. Besides, when a layer is referred to as being “on” another layer or substrate, it may be directly on the other layer or substrate, or maybe on the other layer or substrate, or intervening layers may be included between other layers or substrates.

Besides, relative terms such as “lower” or “bottom”, and “higher” or “top” may be used in embodiments to describe the relative relation of an element to another element labeled in figures. It should be understood that if the labeled device is flipped upside down, the element in the “lower” side may be the element in the “higher” side.

The ordinal numbers such as “first”, “second”, etc. are used in the specification and claims to modify the elements in the claims. It does not mean that the required element has any previous ordinal number, and it does not represent the order of a required element and another required element or the order in the manufacturing method. The ordinal number is just used to distinguish the required element with a certain name and another required element with the same certain name.

It should be noted that the technical features in different embodiments described in the following may be replaced, recombined, or mixed with one another to constitute another embodiment without departing from the spirit of the present disclosure.

In the present disclosure, the electronic device may include a display panel, an antenna device, a sensing device, a tiled device, or a transparent display device but is not limited thereto. The electronic device may include a rollable, stretchable, bendable, or flexible electronic device.

The display panel may include, for example, liquid crystal materials, light-emitting diodes (LED), quantum dot (QD) materials, fluorescence materials, phosphor materials, or other suitable materials, and the above materials may be arbitrarily arranged and combined. The light-emitting diodes may include, for example, organic light-emitting diode (OLED), mini LED, micro LED or quantum dot LED (e.g., QLED or QDLED), but is not limited thereto.

Although some of various drawings illustrate a number of logical stages in a particular order, stages that are not order dependent maybe reordered and other stages maybe combined or broken out. While some reordering or other groupings are specifically mentioned, others will be obvious to those of ordinary skill in the art, so the ordering and groupings presented herein are not an exhaustive list of alternatives. Moreover, it should be recognized that the stages could be implemented in hardware, firmware, software or any combination thereof.

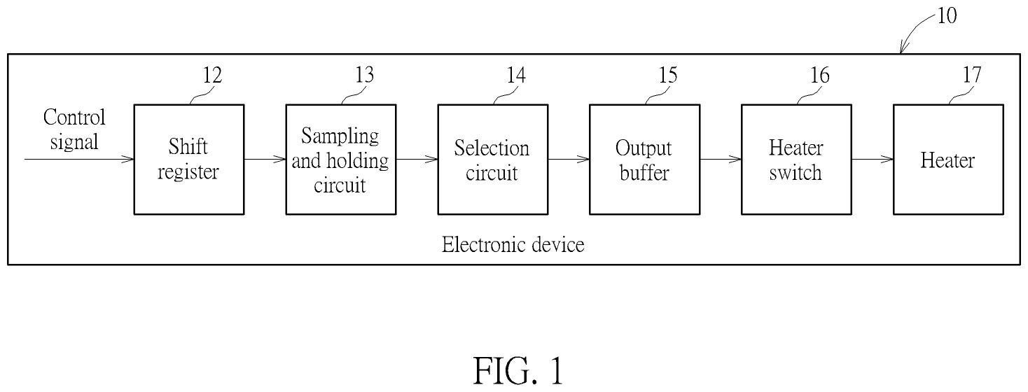

FIG. 1 is a diagram of an electronic device 10 of an embodiment. The electronic device 10 includes a shift register 12, a sampling and holding circuit 13, a selection circuit 14, an output buffer 15, a heater switch 16, and a heater 17. The shift register 12 is used to receive a control signal. The sampling and holding circuit 13 is coupled to the shift register 12. The selection circuit 14 is coupled to the sampling and holding circuit 13. The output buffer 15 is coupled to the selection circuit 14. The heater switch 16 is coupled to the output buffer 15. The heater 17 is coupled to the heater switch 16. For example, the electronic device 10 may be a print head driving circuit, but not limited thereto. The electronic device 10 may include thin film transistors. Generally, inkjet printers include thermal inkjets which can distribute ink supplied from an ink tank to chambers and can selectively generate pressure in each chamber, such that ink droplets can be ejected through a print head connected with each chamber. In other words, the print head driving circuit drives the print head according to the control signal to eject ink droplets from the print head to recreate digital images on a substrate.

The shift register 12 can be a digital circuit that uses a series of flip-flops to store or transfer binary data. Each flip-flop has an output that is connected to the input of the next one. They all share a common clock signal that makes the data move from one flip-flop to another. The shift register 12 can have different modes of operation, such as serial-in, parallel-out (SIPO) or parallel-in, serial-out (PISO). Further, the shift register 12 is used in the electronic device 10 to control the print head. For example, a SIPO shift register can receive serial data from a computer and output it in parallel to the print head. Each bit of data corresponds to a dot on the paper. A PISO shift register can do the opposite—receive parallel data from the print head and output it in serial to the computer. This can be useful for scanning or copying documents.

The selection circuit 14 can be a digital logic circuit that choose one of several input signals and direct it to a single output. It can be used to multiplex different data sources, such as print commands, sensor readings, or status indicators, and send them to the printer controller. The selection circuit 14 can be implemented using various logic gates, such as NAND, XOR, or AND-OR gates. In addition, the selection circuit 14 can have a data select input that determines which input signal is selected for the output.

The heater switch 16 in a printer is a device that controls the power supply to the heating element of the hotend or the heated bed. The heater switch 16 can be a MOSFET that can be turned on or off by a control signal. The heater switch 16 is important for maintaining the desired temperature and preventing overheating or fire hazards. If the temperature exceeds a certain limit, a thermal fuse in the heater switch 16 can assist in cutting off the power.

The heater 17 can help maintain a stable temperature for the printing process. A thermal printer uses a heated print head to activate thermal paper or transfer ink from a ribbon. Hence the heater 17 can improve the print quality and speed of thermal printers.

The sampling and holding circuit 13 and the output buffer 15 are described in detail in the following paragraphs.

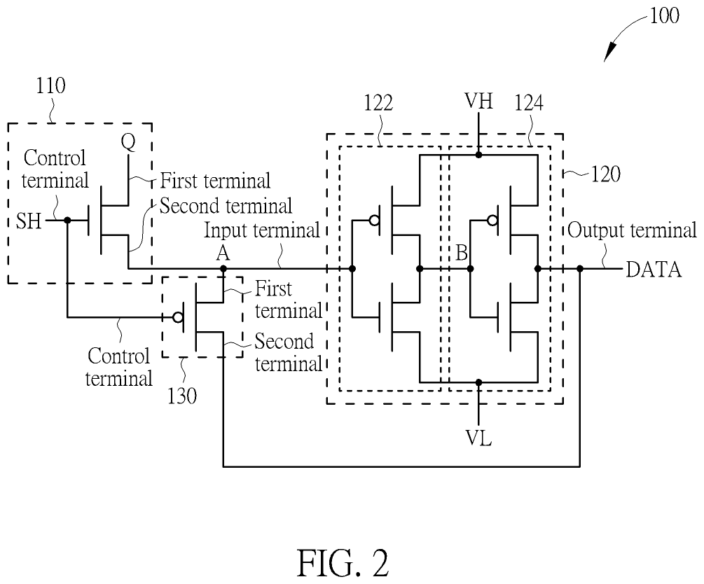

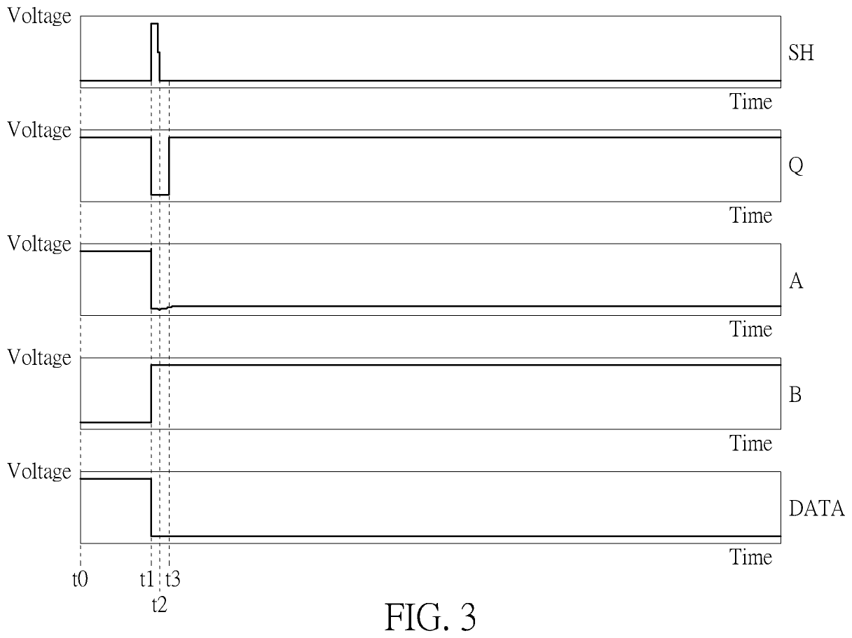

Please refer to FIGS. 2 and 3. FIG. 2 is a circuit diagram of a sampling and holding circuit 100 of an embodiment. The sampling and holding circuit 100 may correspond to the sampling and holding circuit 13 in FIG. 1. The sampling and holding circuit 100 includes a sampling unit 110, a register unit 120 and a feedback unit 130. The sampling unit 110 is for receiving the data signal SH. The register unit 120 has an input terminal and an output terminal. The input terminal is coupled to the sampling unit 110, and the output terminal is used to output a signal DATA. Because an input signal A at the input terminal is prone to leakage causing the signal to be unstable, which results in data loss of the input signal A, the embodiment uses the feedback unit 130 to couple the input terminal of the register unit 120 to the output terminal. Such feedback circuit structure can stabilize the input signal A.

In more detail, the sampling unit 110 includes a control terminal, a first terminal and a second terminal. The second terminal of the sampling unit is coupled to the input terminal. The feedback unit 130 includes a control terminal, a first terminal and a second terminal. The control terminal of the feedback unit 130 is coupled to the control terminal of the sampling unit 110. The first terminal of the feedback unit 130 is coupled to the input terminal of the register unit 120, and the second terminal of the feedback unit 130 is coupled to the output terminal of the register unit 120. The sampling unit 110 may include an N-type thin film transistor, and the feedback unit 130 may include a P-type thin film transistor. In another embodiment, the sampling unit 110 may include a P-type thin film transistor, and the feedback unit 130 may include an N-type thin film transistor. The register unit 120 includes two inverters 122 and 124 coupled to each other. The inverters 122 and 124 are CMOS inverters each formed with a P-type thin film transistor and an N-type thin film transistor connected together at the gates and the drains and driven by the voltage VH and the voltage VL. In this disclosure, the semiconductor material in the transistors may include amorphous silicon, low temperature polysilicon, or metal oxides. Some parts of the transistors in the electronic device 10 may also include low-temperature polysilicon, and the other parts may include metal oxides.

FIG. 3 is a timing diagram of operation signals of the sampling and holding circuit 100 of an embodiment. For example, at time to, the data signal SH may be at a low level, the sampling unit 110 is turned off, and the feedback unit 130 is turned on. The signal Q at the first terminal of the sampling unit 110 may be at a high level, and the signal A at the input terminal of the register unit 120 may be at a high level. The signal B generated by the signal A through the inverter 122 is at a low level, and the signal B is then passed through the inverter 124 to produce an output signal DATA at a high level. The feedback mechanism of the sampling and holding circuit 100 can lock the input signal A, such that the input signal A is substantially equal to the output signal DATA.

From time t1 to t2, the data signal SH becomes a pulse wave. The data signal SH rises to a high level at time t1, the sampling unit 110 is turned on, and the feedback unit 130 is turned off. The signal Q of the first terminal of the sampling unit 110 can drop to a low level at the same time, such that the signal A of the input terminal of the register unit 120 can also drop to a low level. The signal B generated by the signal A through the inverter 122 is at a high level, and the signal B is then passed through the inverter 124 to produce an output signal DATA at a low level. The data signal SH falls to a low level at time t2, such that the sampling unit 110 is turned off, and the feedback unit 130 is turned on.

At time t3, the data signal SH drops to a low level. The sampling unit 110 is turned off, and the feedback unit 130 is turned on. The signal Q of the first terminal of the sampling unit 110 rises back to the high level. At this time, because the sampling unit 110 is turned off, the signal Q would not affect the signals of other parts of the sampling and holding circuit 100.

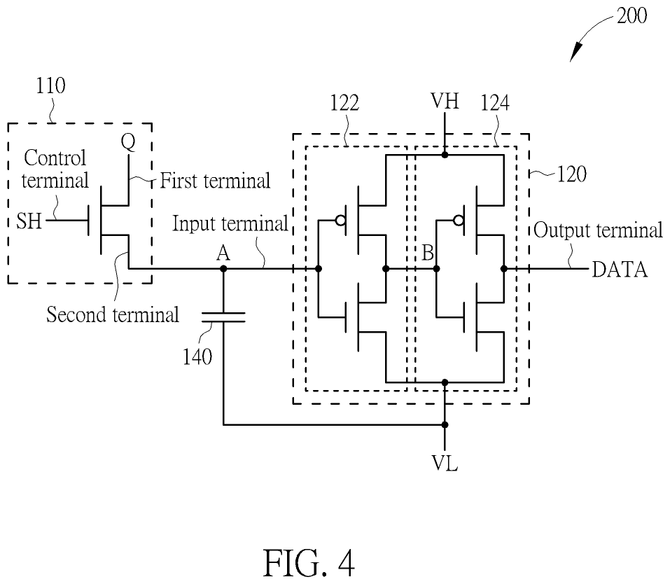

FIG. 4 is a circuit diagram of a sampling and holding circuit 200 of another embodiment. Similar to the previous mentioned sampling and holding circuit 100, the sampling unit 110 of the sampling and holding circuit 200 also includes a control terminal, a first terminal and a second terminal. The register unit 120 also includes two inverters 122 and 124 coupled to each other. The inverters 122 and 124 are CMOS inverters each formed with a P-type thin film transistor and an N-type thin film transistor connected together at the gates and the sources and driven by the voltage VH and the voltage VL. However, the difference between the sampling and holding circuit 200 and the sampling and holding circuit 100 is that the sampling and holding circuit 200 does not include the feedback unit 130; instead, the sampling and holding circuit 200 includes a capacitor 140 coupled between the input terminal of the register unit 120 and the voltage terminal of the voltage VL. The capacitor 140 can be used to reduce the leakage of the input terminal of the register unit 120 to stabilize the signal A at the input terminal of the register unit 120. In some embodiments, the sampling and holding circuit 200 may further include a capacitor coupled between the input terminal of the register unit 120 and the voltage terminal of the voltage VH. Those skilled in the art can vary the design according to the actual implementation.

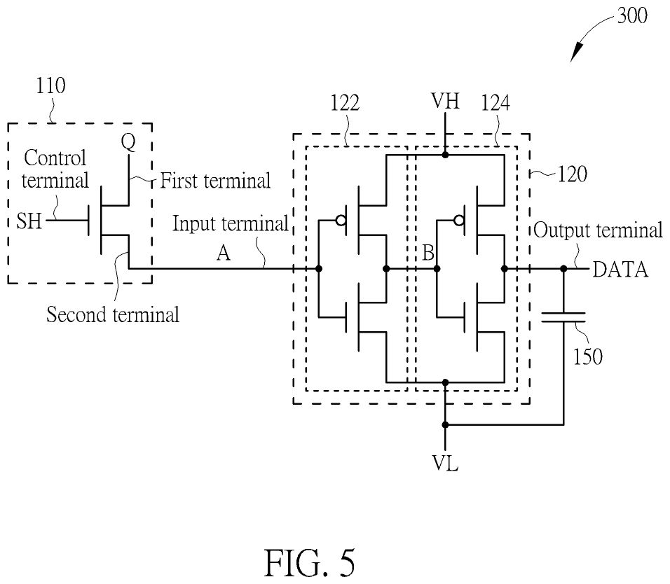

FIG. 5 is a circuit diagram of a sampling and holding circuit 300 of another embodiment. Similar to the previous mentioned sampling and holding circuit 100, the sampling unit 110 of the sampling and holding circuit 300 also includes a control terminal, a first terminal and a second terminal. The register unit 120 also includes two inverters 122 and 124 coupled to each other. The inverters 122 and 124 are CMOS inverters each formed with a P-type thin film transistor and an N-type thin film transistor connected together at the gates and the sources and driven by the voltage VH and the voltage VL. However, the difference between the sampling and holding circuit 300 and the sampling and holding circuit 100 is that the sampling and holding circuit 300 does not include the feedback unit 130; instead, the sampling and holding circuit 300 includes a capacitor 150 coupled between the output terminal of the register unit 120 and the voltage terminal of the voltage VL. The capacitor 150 can be used to reduce the leakage of the output terminal of the register unit 120 to stabilize the signal DATA at the output terminal of the register unit 120. In some embodiments, the sample and hold circuit 300 may further include a capacitor coupled between the output terminal of the register unit 120 and the voltage terminal of the voltage VH. In some other embodiments, the sampling and holding circuit 300 may further include a capacitor coupled between the input terminal of the register unit 120 and the voltage terminal of the voltage VH, and another capacitor coupled between the input terminal of the register unit 120 and the voltage terminal of the voltage VL. Those skilled in the art can vary the design according to the actual implementation.

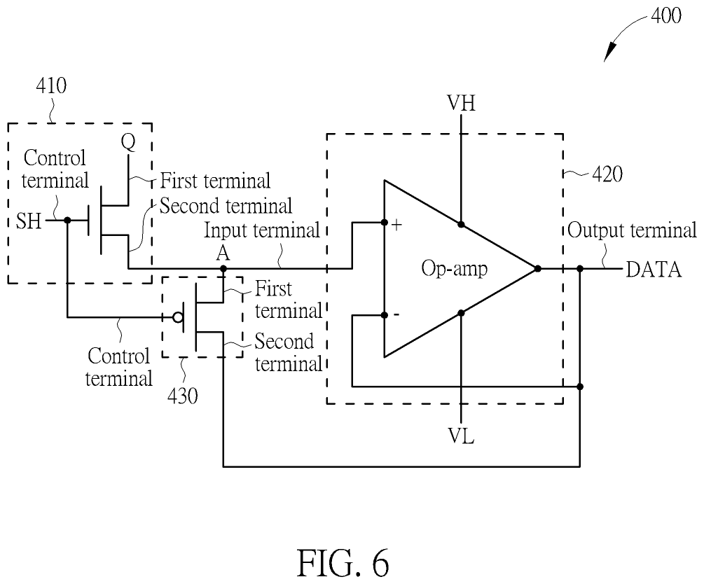

FIG. 6 is a circuit diagram of a sampling and holding circuit 400 of another embodiment. The difference between the sampling and holding circuit 400 and the sampling and holding circuit 100 is that the register unit 420 of the sampling and holding circuit 400 is an operational amplifier. An operational amplifier (op-amp) is a device that can amplify and manipulate electrical signals, such as voltage or current. Op-amps are widely used in electronic circuits, such as filters, oscillators, comparators, integrators, and differentiators. An operational amplifier has two input terminals, one for the positive (non-inverting) input and one for the negative (inverting) input. It also has one output terminal and two power supply terminals. The output of an operational amplifier is proportional to the difference between the two input signals, multiplied by a large gain factor. The gain factor depends on the design and configuration of the operational amplifier and its feedback components. Op-amps are usually connected with resistors or capacitors in a feedback loop, which controls the gain and stability of the circuit. Op-amps can operate in different modes, e.g., linear, non-linear, or differential mode, depending on the application and purpose of the circuit.

In the embodiment, the sampling unit 410 is used for receiving the data signal SH. The register unit 420 includes an inverting input terminal, a non-inverting input terminal and an output terminal. The non-inverting input terminal is coupled to the sampling unit 410, and the output terminal is used to output the signal DATA. In addition, the register unit 420 is driven by the voltages VH and VL. Moreover, the inverting input terminal of the register unit 420 is coupled to the output terminal, and the non-inverting input terminal is coupled to the output terminal through the feedback unit 430 to stabilize the signal A and the output signal DATA by way of circuit feedback. In other words, the signal A of the non-inverting input terminal is substantially equal to the output signal DATA, so as to stabilize each signal of the sampling and holding circuit 400. The operation of the sampling and holding circuit 400 is similar to that of the sampling and holding circuit 100 and the description is not repeated herein for brevity.

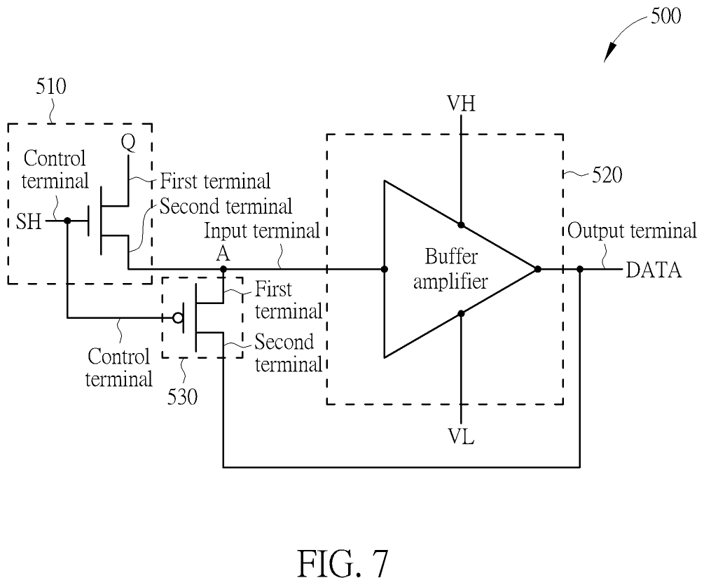

FIG. 7 is a circuit diagram of a sampling and holding circuit 500 of another embodiment. The difference between the sampling and holding circuit 500 and the sampling and holding circuit 100 is that the register unit 520 of the sampling and holding circuit 500 is a buffer amplifier. A buffer amplifier is a type of electronic circuit that isolates the input and output signals of a system. It can be used to prevent the loading effect, which occurs when the input impedance of a device is too low compared to the output impedance of the previous stage. A buffer amplifier can also provide voltage or current gain, depending on the configuration. There are different types of buffer amplifiers, such as voltage followers, emitter followers, source followers, and common-collector amplifiers. Furthermore, a buffer amplifier can be either a voltage buffer or a current buffer, depending on whether it transfers voltage or current from the input to the output. A buffer amplifier can be implemented with discrete components, such as JFETs, or with integrated circuits, such as op-amps. It is useful for applications that require high speed, low noise, high slew rate, fast settling, and fixed gain of 1.

In the embodiment, the sampling unit 510 is used for receiving the data signal SH. The register unit 520 has an input terminal and an output terminal. The input terminal is coupled to the sampling unit 510, and the output terminal is used to output the signal DATA. In addition, the register unit 520 is driven by the voltages VH and VL. Moreover, the input terminal and the output terminal of the register unit 520 are coupled through a feedback unit 530 to stabilize the signals through feedback mechanism. In other words, when the data signal SH is at a low level, the input terminal signal A and the output terminal signal DATA are essentially equal, thus each signal of the sampling and holding circuit 500 can be stabilized. The operation of the sampling and holding circuit 500 is similar to that of the sampling and holding circuit 100, and the description is not be repeated herein for brevity.

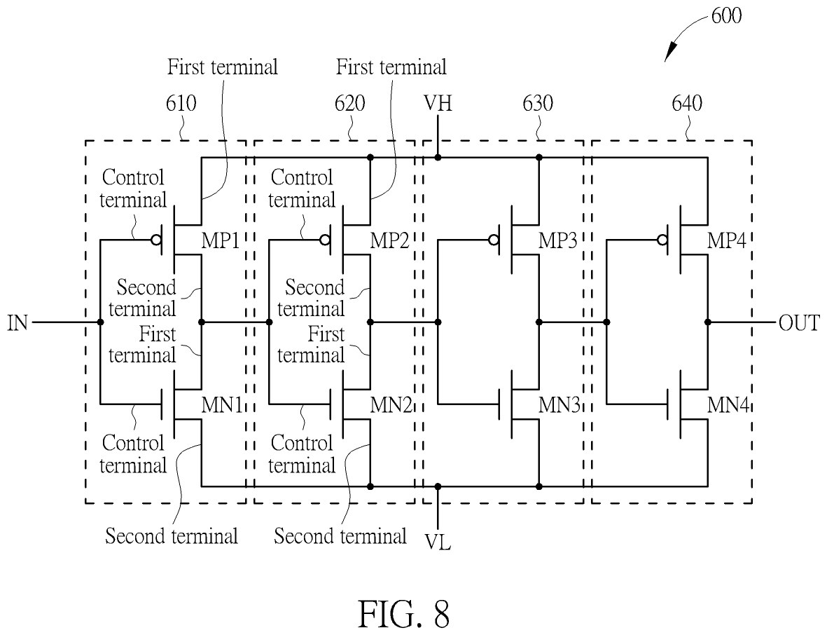

FIG. 8 is a circuit diagram of an output buffer 600 of an embodiment. The output buffer 600 may correspond to the output buffer 15 in FIG. 1. The output buffer 600 includes inverters 610, 620, 630 and 640. The inverter 610 includes a P-type transistor MP1 coupled to an N-type transistor MN1. The inverter 620 includes a P-type transistor MP2 coupled to an N-type transistor MN2. The inverter 630 includes a P-type transistor MP3 coupled to an N-type transistor MN3. The inverter 640 includes a P-type transistor MP4 coupled an N-type transistor MN4. The P-type transistor MP1 includes a control terminal, a first terminal and a second terminal. The control terminal of the P-type transistor MP1 is coupled to the input terminal IN. The P-type transistor MP2 includes a control terminal, a first terminal and a second terminal. The control terminal of the P-type transistor MP2 is coupled to the second terminal of the P-type transistor MP1, and the first terminal of the P-type transistor MP2 is coupled to first terminal of the P-type transistor MP1. The first terminal of the N-type transistor MN1 is coupled to the second terminal of the P-type transistor MP1. The first terminal of the N-type transistor MN2 is coupled to the second terminal of the P-type transistor MP2. The inverter 630 is coupled to the second terminal of the P-type transistor MP2. The inverter 640 is coupled to the inverter 630, and the inverter 640 is coupled to the output terminal OUT. The inverters 610, 620, 630 and 640 can be driven by the voltage VH and the voltage VL. The second terminals of the N-type transistors MN1, MN2, MN3 and MN4 can receive the voltage VL, and the first terminals of the P-type transistors MP1, MP2, MP3 and MP4 can receive the voltage VH. The P-type transistors MP1, MP2, MP3 and MP4 can be P-type thin film transistors, and the N-type transistors MN1, MN2, MN3 and MN4 can be N-type thin film transistors.

The inverters 610 and 620 can be implemented to adjust the difference between rising time and falling time of the driving signal at the output terminal OUT. The inverters 630 and 640 can be implemented to generate the current multiplication effect. Therefore, in terms of design, the channel width-to-length (W/L) ratio of the P-type transistor MP1 is greater than the channel width-to-length ratio (W/L) of the P-type transistor MP2. The channel W/L ratio of the N-type transistor MN1 is smaller than the channel W/L ratio of the N-type transistor MN2. Specifically, the channel W/L ratio of the P-type transistor MP1 is approximately 5 to 10, and the channel W/L ratio of the P-type transistor MP2 is approximately 0.5 to 1. That is, the ratio of the channel W/L ratio of the P-type transistor MP1 to the channel W/L ratio of the P-type transistor MP2 is between 5 and 20. The channel W/L ratio of the N-type transistor MN1 is approximately 0.5 to 1, and the channel W/L ratio of the N-type transistor MN2 is approximately 5 to 10. That is, the ratio of the channel W/L ratio of the N-type transistor MN2 to the channel W/L ratio of the N-type transistor MN1 is between 5 and 20.

In terms of design, the channel W/L ratios of the N-type transistors MN3 and MN4 and the channel W/L ratios of the P-type transistors MP3 and MP4 should be as large as possible to produce the current multiplication effect. In particular, the channel refers to the semiconductor layer between the source and drain of the transistor, which is a conductive layer along the length direction produced by an external electric field. The channel W/L ratio is the ratio of the channel width to the channel length. The saturation current of the transistor increases with increasing channel W/L ratio, which can result in shorter time span in signal rising and falling. In some embodiments, by adjusting the channel W/L ratio, the rising time of the driving signal at the output terminal OUT is longer than the falling time of the driving signal, so as to enhance the isolation between two consecutive driving signals and avoid errors caused by overlapping driving signals. More details are described in the following paragraphs.

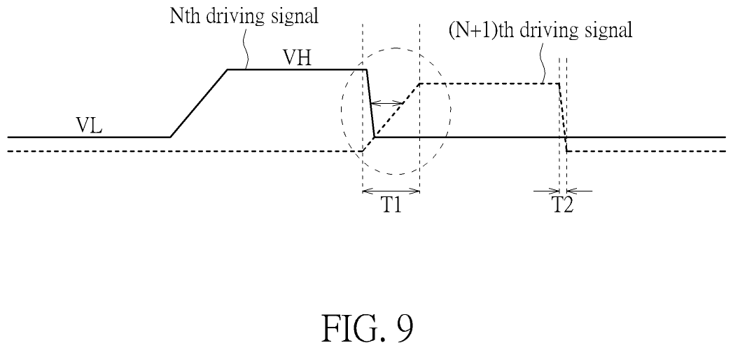

FIG. 9 is a timing diagram of driving signals at the output terminal OUT of the output buffer 600 in FIG. 8. FIG. 9 shows the Nth driving signal and the (N+1)th driving signal (N is a positive integer) of the output buffer 600. The signal waveforms of the input terminal IN and the output terminal OUT of the output buffer 600 are basically similar. As shown in FIG. 9, the output buffer 600 simply changes the amplitude of the signal waveform and the rising and falling slope of the signal waveform. The embodiment takes the Nth and (N+1)th driving signals at the output terminal OUT as an example for illustration. When the driving signal is at a low level, the P-type transistors MP2 and MP4 and the N-type transistors MN1 and MN3 are turned off, and the P-type transistors MP1 and MP3 and the N-type transistors MN2 and MN4 are turned on. When the driving signal is at a high level, the P-type transistors MP1 and MP3 and the N-type transistors MN2 and MN4 are turned off, and the P-type transistors MP2 and MP4 and the N-type transistors MN1 and MN3 are turned on.

As shown in FIG. 9, the time period T1 is the time for the (N+1)th driving signal to rise from the voltage VL to the voltage VH, and the time period T2 is the time for the (N+1)th driving signal to fall from the voltage VH to the voltage VL. When the (N+1)th driving signal rises, the signal is pulled up to a high level (i.e., the level of the voltage VH) mainly by the P-type transistor MP2 and the N-type transistor MN1. Since the channel W/L ratio of the P-type transistor MP2 and the N-type transistor MN1 are relatively small causing the saturation current to be lower, the rising time of the signal is longer, and the slope is small. When the (N+1)th driving signal falls, the signal is pulled down to a low level (i.e., the level of the voltage VL) mainly by the P-type transistor MP1 and the N-type transistor MN2. Since the channel W/L ratios of the P-type transistor MP1 and the N-type transistor MN2 are relatively large causing the saturation current to be relatively high, the falling time of the signal is shorter, and the absolute value of the slope is larger than the slope during the time period T1. As such, the time period T1 is longer than the time period T2. As the result of such configuration, the overlapping portion of the Nth driving signal and the (N+1)th driving signal can be reduced, effectively avoiding operational errors of the thermal inkjet caused by the overlapping signals. Since the operation principles of the transistors MN3, MN4, MP3 and MP4 are basically the same as those of the transistors MN1, MN2, MP1 and MP2, those skilled in the art can deduce them to practice accordingly. The description is not repeated herein for brevity.

It should be noted that the Nth driving signal and the (N+1)th driving signal should have approximately the same amplitude. The drawing of the driving signals in FIG. 9 looks staggered for illustration purpose.

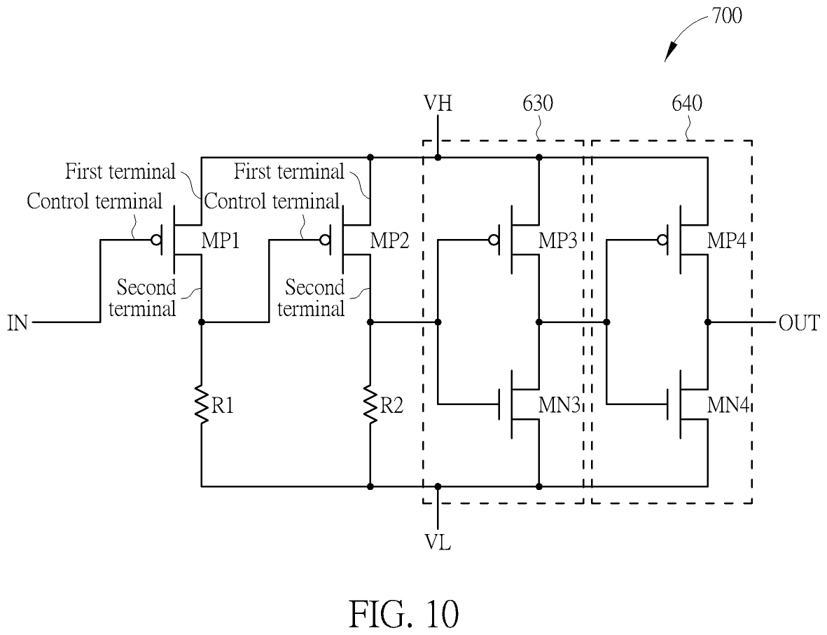

FIG. 10 is a circuit diagram of an output buffer 700 of another embodiment. The primary difference between the output buffer 700 and the output buffer 600 is that the N-type transistors MN1 and MN2 can be replaced by resistors R1 and R2 respectively. The resistor R1 can be coupled between the second terminal of the P-type transistor MP1 and the voltage terminal of the voltage VL. The resistor R2 can be coupled between the second terminal of the P-type transistor MP2 and the voltage terminal of the voltage VL.

When the (N+1)th driving signal rises, the signal is pulled up to a high level (i.e., the level of the voltage VH) mainly by the P-type transistor MP2. Since the channel W/L ratio of the P-type transistor MP2 is relatively small causing the saturation current to be lower, the rising time of the (N+1) driving signal is longer, and the slope is small. When the (N+1)th driving signal falls, the (N+1)th driving signal is pulled down to a low level (i.e., the level of the voltage VL) mainly by the P-type transistor MP1. Since the channel W/L ratios of the P-type transistor MP1 is relatively large causing the saturation current to be relatively high, the falling time of the signal is shorter, and the absolute value of the slope is larger than the slope during the rising time of the (N+1)th driving signal. As such, the time period T1 is longer than the time period T2 (as shown in FIG. 9). As the result of such configuration, the overlapping portion of the Nth driving signal and the (N+1)th driving signal can be reduced, effectively avoiding operational errors of the thermal inkjet caused by the overlapping signals. The other operation principles of the output buffer 700 are similar to those of the output buffer 600, and those skilled in the art can deduce them to practice accordingly. The description is not repeated herein for brevity.

Because the inverters 610 and 620 in FIG. 8 are implemented to control the rising and falling slopes of the signals, it is necessary to be able to more precisely manufacture the channel W/L ratios of the transistors MP1, MP2, MN1, and MN2. As such, the requirement for the transistor manufacturing process may be much higher. By replacing the N-type transistors MN1 and MN2 with the resistors R1 and R2 respectively, the number of transistors can be reduced, thus lowering the precision requirement for the manufacturing process.

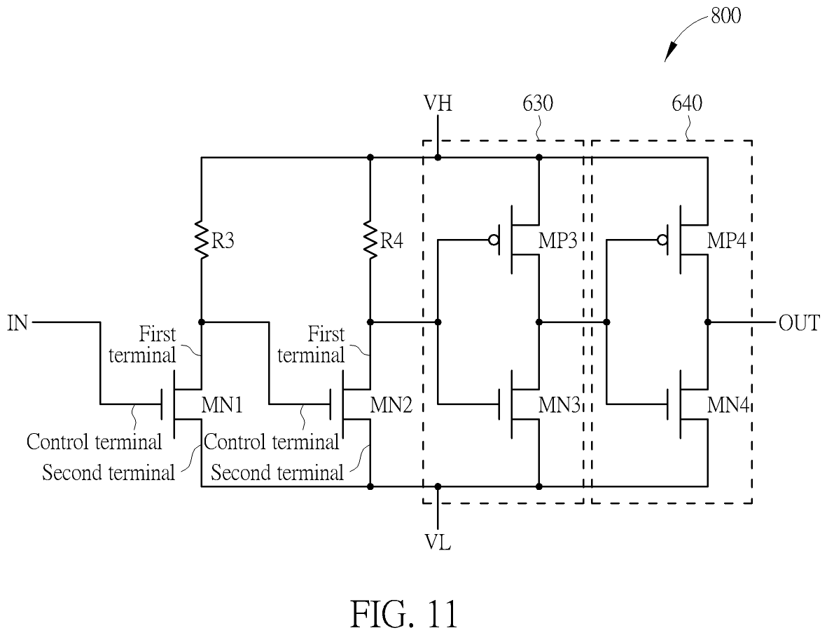

FIG. 11 is a circuit diagram of an output buffer 800 of another embodiment. The primary difference between the output buffer 800 and the output buffer 600 is that the P-type transistors MP1 and MP2 can be replaced by resistors R3 and R4 respectively. The resistor R3 can be coupled between the first terminal of the N-type transistor MN1 and the voltage terminal of the voltage VH. The resistor R4 can be coupled between the first terminal of the N-type transistor MN2 and the voltage terminal of the voltage VH.

When the Nth driving signal rises, the signal is pulled up to a high level (i.e., the level of the voltage VH) mainly by the N-type transistor MN1. Since the channel W/L ratio the N-type transistor MN1 is relatively small causing the saturation current to be lower, the rising time of the (N+1)th driving signal is longer, and the slope is small. When the Nth driving signal falls, the signal is pulled down to a low level (i.e., the level of the voltage VL) mainly by the N-type transistor MN2. Since the channel W/L ratios of the N-type transistor MN2 is relatively large causing the saturation current to be relatively high, the falling time of the Nth driving signal is shorter, and the absolute value of the slope is larger than the slope during the rising time of the (N+1)th driving signal. As such, the time period T1 is longer than the time period T2 (as shown in FIG. 9).As the result of such configuration, the overlapping portion of the Nth driving signal and the (N+1)th driving signal can be reduced, effectively avoiding operational errors of the thermal inkjet caused by the overlapping signals. The other operation principles of the output buffer 800 are similar to those of the output buffer 600, and those skilled in the art can deduce them to practice accordingly. The description is not repeated herein for brevity.

Because the inverters 610 and 620 in FIG. 8 are implemented to control the rising and falling slopes of the signals, it is necessary to be able to more precisely manufacture the channel W/L ratios of the transistors MP1, MP2, MN1, and MN2. As such, the requirement for the transistor manufacturing process may be much higher. By replacing the P-type transistors MP1 and MP2 with the resistors R3 and R4 respectively, the number of transistors can be reduced, thus lowering the precision requirement for the manufacturing process.

In summary, the electronic devices described in the various embodiments of this disclosure can effectively reduce the leakage current caused by thin film transistors, and improve rising and falling time of the driving signal. Therefore, it can avoid operation errors of the electronic device caused by leakage current or overlap of driving signals.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising:
a heater; and
a sampling and holding circuit coupled to the heater, comprising:
a sampling unit configured to receive a data signal;
a register unit having an input terminal and an output terminal, the input terminal being coupled to the sampling unit, and the output terminal being configured to output a first signal; and
a feedback unit coupled to the input terminal and the output terminal of the register unit;
wherein when the feedback unit is turned on, the feedback unit feeds back the first signal to the input terminal.

2. The electronic device of claim 1, wherein:
the sampling unit comprises a control terminal, a first terminal, and a second terminal coupled to the input terminal;
the feedback unit comprises a control terminal, a first terminal and a second terminal; and
the control terminal of the feedback unit is coupled to the control terminal of the sampling unit, the first terminal of the feedback unit is coupled to the input terminal, and the second terminal of the feedback unit is coupled to the output terminal.

3. The electronic device of claim 1, wherein the sampling unit comprises a first-type thin film transistor, the feedback unit comprises a second-type thin film transistor, and the first type is either an N-type or P-type, the second type is the other one of N-type and P-type.

4. The electronic device of claim 1, wherein the register unit comprises two inverters coupled to each other.

5. The electronic device of claim 1, wherein the register unit is an operational amplifier.

6. The electronic device of claim 5, wherein the input terminal is a non-inverting input terminal of the operational amplifier, and the output terminal is coupled to an inverting input terminal of the operational amplifier.

7. The electronic device of claim 1, wherein the register unit is a buffer amplifier.

8. The electronic device of claim 1, wherein the heater is a thermal inkjet.

9. An electronic device comprising:
a sampling and holding circuit configured to receive a data signal and output a first signal;
an output buffer coupled to the sampling and holding circuit, and configured to receive the first signal and output a driving signal; and
a heater coupled to the output buffer, and configured to receive the driving signal;
wherein a rising time of the driving signal has a first time period, a falling time of the driving signal has a second time period, and the first time period is longer than the second time period.

10. The electronic device of claim 9, wherein the output buffer comprises:
a first P-type transistor having a control terminal, a first terminal and a second terminal;
a second P-type transistor having a control terminal, a first terminal and a second terminal, the control terminal of the second P-type transistor being coupled to the second terminal of the first P-type transistor, and the first terminal of the second P-type transistor being coupled to the first terminal of the first P-type transistor;
a first inverter coupled to the second terminal of the second P-type transistor; and
a second inverter coupled to the first inverter;
wherein a channel width-to-length ratio of the first P-type transistor is greater than a channel width-to-length ratio of the second P-type transistor.

11. The electronic device of claim 10, wherein the channel width-to-length ratio of the first P-type transistor is 5 to 10 and the channel width-to-length ratio of the second P-type transistor is 0.5 to 1.

12. The electronic device of claim 10, wherein a ratio of the channel width-to-length ratio of the first P-type transistor to the channel width-to-length ratio of the second P-type transistor is 5 to 20.

13. The electronic device of claim 10, wherein the output buffer further comprises:
a first N-type transistor coupled to the second terminal of the first P-type transistor; and
a second N-type transistor coupled to the second terminal of the second P-type transistor;
wherein a channel width-to-length ratio of the first N-type transistor is smaller than a channel width-to-length ratio of the second N-type transistor.

14. The electronic device of claim 13, wherein the channel width-to-length ratio of the first N-type transistor is 0.5 to 1 and the channel width-to-length ratio of the second N-type transistor is 5 to 10.

15. The electronic device of claim 13, wherein a ratio of the channel width-to-length ratio of the second N-type transistor to the channel width-to-length ratio of the first N-type transistor is 5 to 20.

16. The electronic device of claim 10, wherein the output buffer further comprises a first resistor coupled to the second terminal of the first P-type transistor, and a second resistor coupled to the second terminal of the second P-type transistor.

17. The electronic device of claim 9, wherein the heater is a thermal inkjet.

18. The electronic device of claim 9, wherein the output buffer comprises:
a first N-type transistor having a control terminal, a first terminal and a second terminal;
a second N-type transistor having a control terminal, a first terminal and a second terminal, the control terminal of the second N-type transistor being coupled to the first terminal of the first N-type transistor, and the second terminal of the second N-type transistor being coupled to the second terminal of the first N-type transistor;
a first inverter coupled to the first terminal of the second N-type transistor; and
a second inverter coupled to the first inverter;
wherein a channel width-to-length ratio of the first N-type transistor is less than a channel width-to-length ratio of the second N-type transistor.

19. The electronic device of claim 17, wherein a ratio of the channel width-to-length ratio of the second N-type transistor to the channel width-to-length ratio of the first N-type transistor is 5 to 20.

20. The electronic device of claim 17, wherein the output buffer further comprises a third resistor coupled to the first terminal of the first N-type transistor, and a fourth resistor coupled to the first terminal of the second N-type transistor.
